(19) United States
(12) Patent Application Publication
(10) Pub. No.: US 2005/0206545 A1
(43) Pub. Date: Sep. 22, 2005

(54) Holding method, analog to digital converting method, signal observing method, holding apparatus, analog to digital converting apparatus, and signal observing apparatus

(75) Inventors: Haruo Kobayashi, Gunma (JP); Naoto Hayasaka, Miyagi (JP); Takanori Komuro, Tokyo (JP)

Correspondence Address: Paul D. Greeley, Esq.;Ohlandt, Greeley, Ruggiero & Perle, L.L.P., One Landmark Square, 10th Floor, Stamford, CT, 06901-2682, US

(73) Assignee: AGILENT TECHNOLOGIES, INC.

(21) Appl. No.: 11/055,419

(22) Filed: Feb. 10, 2005

(30) Foreign Application Priority Data
Mar. 5, 2004 (JP) 2004-063087

(51) Int. Cl. H03M 1/66

(52) U.S. Cl. 341/145

(57) ABSTRACT

A method for performing the analog to digital conversion of a repeating signal that includes performing the analog conversion of digital data and generating a reference signal, comparing the repeating signal and the reference signal, holding the comparison result at a prescribed time position of the repeating signal, and adjusting the digital data based on the held comparison result. In addition, an apparatus for performing the analog to digital conversion of a repeating signal by implementing the method described above.

### FIELD OF THE INVENTION

The present invention relates to technology for observing a signal under test in a device under test.

### DISCUSSION OF THE BACKGROUND ART

Wireless devices such as cellular phones and wireless local area network (LAN) adapters have internally installed, high-frequency mixed-analog large-scale integrated (LSI) circuits. In the past, high-frequency mixed-analog LSIs were tested by using test equipment such as semiconductor testers, oscilloscopes, or spectrum analyzers (for example, refer to Japanese examined utility model application publication No. 3,071,099 (page 6, FIG. 2)).

Every year, high-frequency mixed-analog LSIs increase in size and speed. However, measurement resources that match the function and the performance of the high-frequency mixed-analog LSIs are difficult to introduce. As high-frequency mixed-analog LSIs speed up, that is, as the frequencies of the signals output by LSIs increase, signal degradation problems such as the attenuation or distortion of the signal under test become apparent. Consequently, the transmission paths between the testing devices and the LSIs, as well as the testing devices themselves become expensive. Tests simplified by the loopback method are low cost, but the problem is that tests having the required specification cannot be conducted.

To solve the above-mentioned problems, the object of the present invention is to provide a method and an apparatus for observing signals under test suited to the Built-In Self-Test (BIST). Holding the signals in LSIs is difficult because the latest high-frequency mixed-analog LSIs are designed for a CMOS process. Therefore, the object of the present invention is to provide a method and an apparatus suited to a Built-In Self-Test (BIST) and which are capable of observing signals easily held in LSIs.

### SUMMARY OF THE INVENTION

A method for holding a repeating signal for analog to digital conversion and includes comparing the repeating signal to a reference signal, and holding the comparison result at the prescribed time position of the repeating signal.

An apparatus for holding the repeating signal for analog to digital conversion and which provides means for comparing the repeating signal to a reference signal, and means for holding the comparison result at the prescribed time position of the repeating signal.

A method for the analog to digital conversion of the repeating signal and includes performing the analog conversion of digital data and generating the reference signal, comparing the repeating signal to the reference signal, holding the comparison result at the prescribed time position of the repeating signal, adjusting the digital data based on the held comparison result, and outputting the digital data as the result of the analog to digital conversion.

An apparatus for performing the analog to digital conversion of the repeating signal and which provides means for performing the analog conversion of digital data and generating a reference signal, means for comparing the repeating signal and the reference signal, means for holding the comparison result at the prescribed time position of the repeating signal, means for adjusting the digital data based on the held comparison result, and means for outputting the digital data as the result of the analog to digital conversion.

A method for the analog to digital conversion of a repeating signal in a device under test, and includes applying the pulses generated at the prescribed time positions of the repeating signal to the device under test, applying the reference signal generated by the analog conversion of the digital data to the device under test, adjusting the digital data based on the received result where the comparison result in the device under test is between the repeating signal and the reference signal and the comparison result held in response to a pulse was received from the device under test, and outputting the digital data as the result of the analog to digital conversion.

An apparatus for performing the analog to digital conversion of a repeating signal in a device under test, and includes means for applying the pulses generated at the prescribed time positions of the repeating signal to the device under test, means for applying the reference signal generated by the analog conversion of digital data to the device under test, means for adjusting the digital data based on the received result where the comparison result in the device under test is between the repeating signal and the reference signal and the comparison result held in response to a pulse was received from the device under test, and means for outputting the digital data as the result of the analog to digital conversion.

A pipelined analog to digital converting apparatus that is provided with a plurality of analog to digital converters and performs the analog to digital conversion of a repeating signal. The analog to digital converters have analog to digital conversion means, digital to analog conversion means, signal holding means, and calculation means. The signals input to the analog to digital converters are applied to the respective signal holding means and calculation means. The signal holding means holds the signal input to the analog to digital converter at the prescribed time position of the repeating signal. The analog to digital conversion means performs the analog to digital conversion of the output signals from the holding means. The digital to analog conversion means performs the analog conversion of the digital data output by the analog to digital conversion means. The calculation means determines the difference between the signal input to an analog to digital converter and the output signal of the digital to analog conversion means, and outputs the difference to a later connected analog to digital converter.

Preferably, the prescribed time position is a position offset by the specified time interval from the time when the repeating signal satisfies prescribed conditions.

Alternatively, the prescribed time position is a position offset by the specified time interval from the time when the repeating signal satisfies prescribed conditions.

According to the present invention, the level accuracy demanded by the holding circuit is lowered compared to the overall required accuracy. Therefore, the signal holding circuit is easily incorporated into LSIs. The result is the ability to observe signals suited to conventional BIST.

### BRIEF DESCRIPTION OF THE DRAWINGS

FIG. 1 is a block diagram of the analog to digital converting apparatus 100 which is the first embodiment of the present invention.

FIG. 2 is a block diagram of the pulse generator 10.

FIG. 3 is a timing chart illustrating the operation of the pulse generator 10.

FIG. 4 is a timing chart illustrating the operation of the analog to digital converting apparatus 100.

FIG. 5 is a block diagram of the analog to digital converting apparatus 200 of the second embodiment of the present invention.

FIG. 6 is block diagram of the difference amplifier 210.

FIG. 7 is a block diagram of the track-and-hold circuit 220.

FIG. 8 is a block diagram of the track-and-hold circuit 220.

FIG. 9 is a timing chart illustrating the operation of the analog to digital converting apparatus 200.

FIG. 10 is a block diagram of the analog to digital converting apparatus 300 of the third embodiment of the present invention.

FIG. 11 is a block diagram of track-and-hold circuit 311-0 and track-and-hold circuit 311-1 to track-and-hold circuit 311-n.

FIG. 12 is a block diagram of track-and-hold circuit 311-0 and track-and-hold circuit 311-1 to track-and-hold circuit 311-n.

FIG. 13 is a block diagram of the analog to digital converting apparatus 400 which is the fourth embodiment of the present invention.

FIG. 14 is a block diagram of the analog to digital converting apparatus 500 which is the fifth embodiment of the present invention.

FIG. 15 is a block diagram of the test system 1000 which is the sixth embodiment of the present invention.

FIG. 16 is a block diagram of the test system 2000 which is the seventh embodiment of the present invention.

FIG. 17 is a block diagram of the test system 3000 which is the eighth embodiment of the present invention.

### DETAILED DESCRIPTION OF THE PREFERRED EMBODIMENT

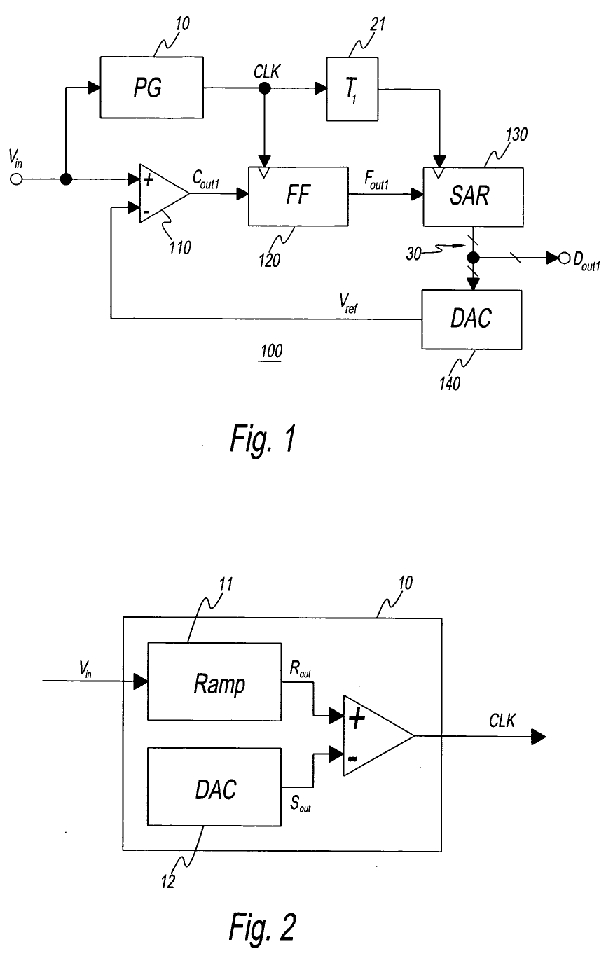

Embodiments of the present invention are explained below while referring to the attached drawings. A first embodiment of the present invention is a successive-approximation analog to digital converting apparatus incorporated into an integrated circuit. FIG. 1 is a block diagram of an analog to digital converting apparatus 100, which is the first embodiment of the present invention. In FIG. 1, the analog to digital converting apparatus 100 has the following structure.

The analog to digital converting apparatus 100 comprises a pulse generator 10 indicated by PG; a delay 21; a comparator 110; a flip-flop 120; a successive-approximation register 130, which is a successive-approximation logic circuit; and a digital to analog converter 140. The signal under test Vᵢₙ is inputted to the analog to digital converting apparatus 100. In all of the embodiments of the present invention, the signal under test Vᵢₙ is a sine wave signal. The signal under test Vᵢₙ can be other types of repeating signals other than the sine wave signal. Hereinafter, the successive-approximation register is also referred to as SAR. In addition, the digital to analog converter is also referred to as DAC. Furthermore, the flip-flop is also referred to as FF. The pulse generator 10 generates pulses at time positions offset by only the specified time interval from the times when the input signal satisfies the specified conditions. The output signal CLK of the pulse generator 10 is supplied to the FF 120 and through the delay having the delay time T₁ to the SAR 130. The FF 120 and the SAR 130 operate in response to the rising edges of the output signal CLK. The delay time T₁ is set to at least the propagation delay time of FF 120 to eliminate the effect of the propagation delay of the FF 120. The signal under test Vᵢₙ and the output signal V_{ref} of the DAC 140 are input to the comparator 110. The comparator 110 outputs the comparison result Cₒᵤₜ₁ to the FF 120. The FF 120 outputs the held data to the SAR 130. In a typical successive-approximation analog to digital converter, SAR is directly connected to the output terminal of the comparator. The analog to digital converter is also referred to as ADC. SAR 130 outputs data through the data bus 30 to the DAC 140 and the data output terminal Dₒᵤₜ₁. Data output from the SAR 130 is the result of the analog to digital conversion of the signal under test Vᵢₙ. In this embodiment, the register length (resolution) of the SAR 130, the resolution of the DAC 140, and the width of the data bus 30 are each 4 bits. In practice, these values can be values other than 4 bits. For example, these values can be 12 bits. The output level range of DAC 140 includes the amplitude range of the signal under test Vᵢₙ.

Next, the operation of the pulse generator 10 is explained. Then, the operation of the analog to digital converting apparatus 100 is explained.

First, to explain the internal structure and operation of the pulse generator 10, FIG. 2 is referenced. FIG. 2 is a block diagram of the pulse generator 10. In FIG. 2, the pulse generator 10 provides a ramp signal generator 11 denoted by Ramp, a DAC 12, and a comparator 13. The ramp signal generator 11 generates the ramp waveform in response to a zero crossing at the rise time of the signal under test Vᵢₙ, which is the input signal. The ramp waveform has a slope extending over at least one period of the signal under test Vᵢₙ. The comparator 13 compares the output signal Rout of the ramp signal generator 11 to the output signal Sₒᵤₜ of the DAC 12 and outputs the comparison result CLK. If the level of the output signal Rₒᵤₜ is less than the level of the output signal Sₒᵤₜ, the output signal of the comparator 13 has the logic level “L”. If the level of the output signal Rₒᵤₜ is greater than the level of the output signal Sₒᵤₜ, the output signal of the comparator 13 has logic level “H”.

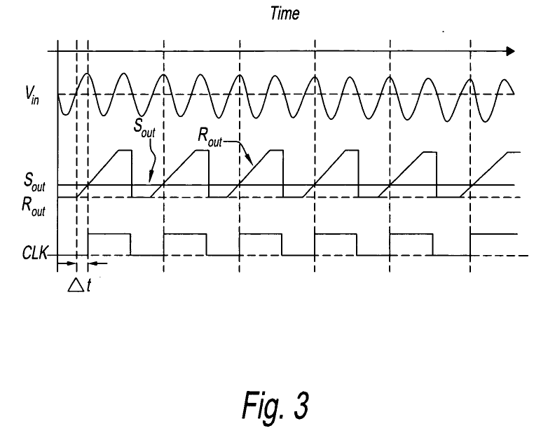

Next, FIG. 3 is referenced. FIG. 3 shows the changes over time of the signal under test Vᵢₙ, output signal Sₒᵤₜ, output signal Rₒᵤₜ, and output signal CLK in FIG. 2. In FIG. 3, the horizontal axis is the time, and the vertical axis is the amplitude or the logic level. In FIG. 3, the pulses are generated at the time positions offset by only Δt from the zero crossings of the rise times of the signal under test Vᵢₙ. This Δt is controlled by the digital value given to the DAC 12. The DAC 12 converts the output signal level according to the given digital value. Consequently, pulses can be generated at the time positions by controlling the digital value for the DAC 12, which the time positions are offset with an arbitrary time from the zero crossings in rising of the signal under test Vin. The output signal of the pulse generator 10 is used as the timing pulses for sampling and analog to digital conversion. These timing pulses are also referred to as the sampling pulses or the sampling clock.

The pulse generator 10 can be an apparatus that generates pulses at time positions offset by only a specified time interval from the times when the input signal satisfies the specified conditions. Thus, the pulse generator 10 is not limited to the structure shown in FIG. 2 and can be implemented by another technology. For example, technology related to sequential sampling can be applied to implement a pulse generator 10 having a different structure than the structure shown in FIG. 2.

Next, the operation of the analog to digital converting apparatus 100 is explained. FIG. 1 is referenced. The comparator 110 compares the levels of the signal under test Vᵢₙ and the reference signal V_{ref} output by the DAC 140, and outputs the comparison result Cₒᵤₜ₁. The comparison result Cₒᵤₜ₁ is output as logic level “H” or “L”. The FF 120 holds the output signal Cₒᵤₜ₁ of the comparator 110, that is, the comparison result, in response to a rising edge of the sampling pulse CLK. FF 120 outputs the held comparison result to the SAR 130. The SAR 130 judges the output signal Fₒᵤₜ, of the FF 120 in response to a rising edge of the sampling pulses CLK and outputs new data. At this time, the SAR 130 updates the content of the internal register. The DAC 140 outputs a new reference signal V_{ref} based on the new data output by the SAR 130.

A conventional analog to digital converting apparatus provides a track-and-hold circuit, which is the signal holding means before the comparator. An element or circuit or apparatus having the track-and-hold function is also referred to as T&H. In the analog to digital converting apparatus 100 of the present invention, the signal under test Vᵢₙ is directly input to the comparator 110. Therefore, there is no regular stable signal period in the output signal Cₒᵤₜ₁ of the comparator 110. To solve this problem, the FF 120 holds the output signal Cₒᵤₜ₁ in response to the sampling pulses CLK. Thus, the output signal Cₒᵤₜ₁ is held at the prescribed time positions of the signal under test Vᵢₙ. Since the signal under test Vᵢₙ is a repeating signal, the same value is held each time because the output signal Cₒᵤₜ₁ is held at the same time positions of the signal under test Vᵢₙ. The analog to digital converting apparatus 100 performs the successive approximation by using this effect.

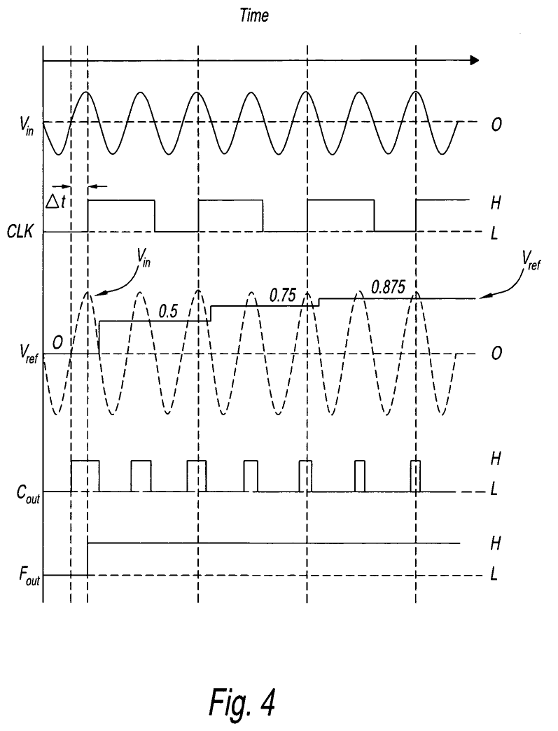

Next, FIG. 1 and FIG. 4 are referenced. FIG. 4 shows the changes over time of the signal under test Vᵢₙ, sampling pulses CLK, reference signal V_{ref}, output signal Cₒᵤₜ₁, and output signal Fₒᵤₜ in FIG. 1. In FIG. 4, the horizontal axis is the time, and the vertical axis is the amplitude or the logic level. Furthermore, at the time of the left edge of the graph, the output data of SAR 130 is “1000”, and the output signal level of the DAC 140 is zero. The bit sequence showing the data contents indicates the most significant bit on the left end and the least significant bit on the right end. The sampling pulses CLK are generated at the time positions offset by only Δt from the zero crossings of the rise times of the signal under test Vᵢₙ. The instantaneous value of the signal under test Vᵢₙ at a time position offset by only Δt is set to 0.975.

In FIG. 4, at the time of the rising edge of the initial, that is, the first from the left sampling pulse CLK, the instantaneous value of the signal under test Vᵢₙ is 0.975 and the reference signal V_{ref} is zero. Consequently, the logic level of the output signal Cₒᵤₜ₁ is “H”, and the logic level held by the FF 120 is “H”. As a result, the output data of SAR 130 becomes “1100”, and the reference signal V_{ref} output from the DAC 140 becomes 0.5.

At the time of the rising edge of the next, that is, the second from the left sampling pulse CLK, the instantaneous value of the signal under test Vᵢₙ is 0.975, and the reference signal V_{ref} is 0.5. Consequently, the logic level of the output signal Cₒᵤₜ₁ is “H”, and the logic level held by the FF 120 is “H”. As a result, the output data of the SAR 130 becomes “1110”, and the reference signal V_{ref} output from the DAC 140 becomes 0.75.

At the time of the rising edge of the next, that is, the third from the left sampling pulse CLK, the instantaneous value of the signal under test Vᵢₙ is 0.975, and the reference signal V_{ref} is 0.75. Consequently, the logic level of the output signal Cₒᵤₜ₁ is “H”, and the logic level held by the FF 120 is “H”. As a result, the output data of the SAR 130 becomes “1111”, and the reference signal V_{ref} output from the DAC 140 becomes 0.875.

At the time of the rising edge of the next, that is, the fourth from the left sampling pulse CLK, the instantaneous value of the signal under test Vᵢₙ is 0.975, and the reference signal V_{ref} is 0.875. Consequently, the logic level of the output signal Cₒᵤₜ₁ is “H”, and the logic level held by the FF 120 is also “H”. Then the analog to digital conversion ends. When the next analog to digital conversion starts, the SAR 130 initializes the internal register and sets the output data to “1000”.

As explained above, in the analog to digital converting apparatus 100, if the comparison result Cₒᵤₜ₁ of the comparator 110 is held at the prescribed time position of the signal under test Vᵢₙ, the level accuracy demanded by the means 120 for holding the comparison result Cₒᵤₜ₁ is lowered to 1 bit, and successive-approximation analog to digital conversion similar to conventional conversion can be performed.

As is clearly seen from FIG. 4, the comparator 110 demands high-speed operation. The frequency of the signal under test Vᵢₙ is assumed to be at least 1 GHz, and the comparator 110 may result in an incomplete comparison operation. The analog to digital converting apparatus that solves this problem is explained below as the second embodiment of the present invention.

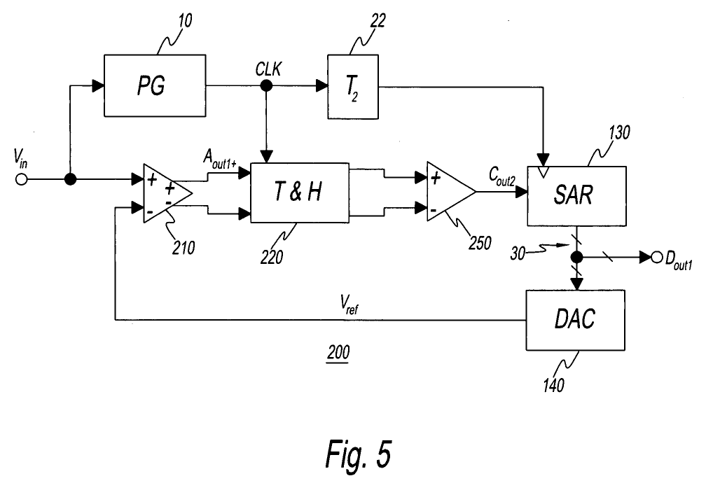

Similarly, a second embodiment of the present invention is a successive-approximation analog to digital converting apparatus incorporated into an integrated circuit. FIG. 5 is a block diagram of an analog to digital converting apparatus 200, which is a second embodiment of the present invention. In FIG. 5, the same structural elements as in FIG. 1 are assigned the same reference numbers and the detailed descriptions are omitted. In FIG. 5, the analog to digital converting apparatus 200 has the following structure.

The analog to digital converting apparatus 200 replaces the comparator 110 and FF 120 in the analog to digital converting apparatus 100 shown in FIG. 1 with a difference amplifier 210, a track-and-hold circuit 220, and a comparator 250. Accompanying this, delay 21 is replaced by delay 22.

The sampling pulses CLK, which are the output signal of the pulse generator 10, are supplied to the T&H 220 and through the delay 22 having a delay time of T₂ to the SAR 130. The T&H 220 operates in response to the logic levels of the sampling pulses CLK. The SAR 130 operates in response to the rising edges of the sampling pulses CLK. In order to eliminate the effect of the total propagation delay of the T&H 220 and the comparator 250, the delay time T₂ is set to at least the propagation delay time of the T&H 220 and the comparator 250. The signal under test Vᵢₙ and the reference signal V_{ref}, which is the output signal of the DAC 140, are input to the difference amplifier 210. The difference amplifier 210 outputs the difference signal of the two input signals to the T&H 220. The T&H 220 outputs the held difference signal to the comparator 250. The comparator 250 outputs the output signal Cₒᵤₜ₂ to the SAR 130.

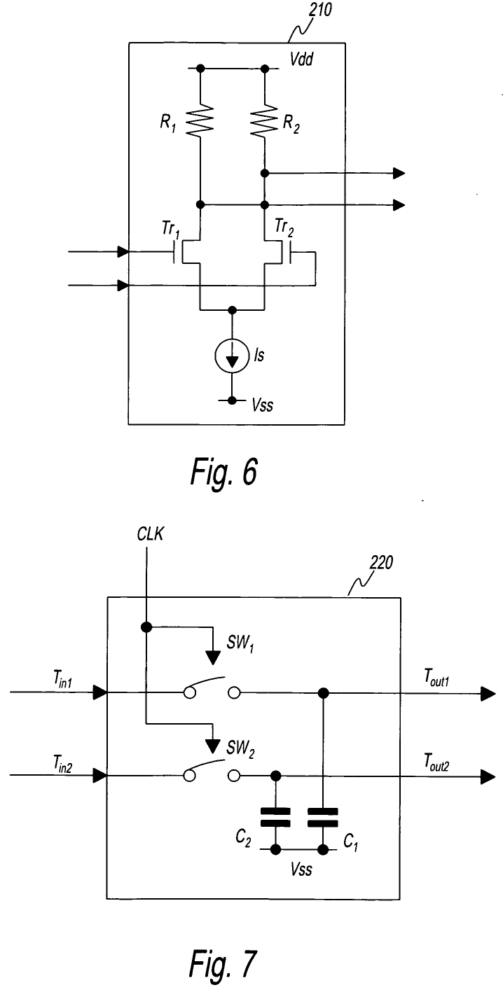

The difference amplifier 210 is a differential input-differential output amplifier. The difference amplifier 210, for example, has the structure shown in FIG. 6. Namely, the difference amplifier 210 is a typical difference amplifier where the sources of transistor Tr1 having drain load resistor R1 and transistor Tr2 having drain load resistor R2 are connected, and the sources of the transistors are connected to a current source. In the drawing, Vdd is a positive voltage source, and Vss is a negative voltage source. The gate of each transistor forms an input of the difference amplifier 210, and the drain of each transistor forms an output of the difference amplifier 210. The resistances of the drain load resistors R1 and R2 are about 1 kilo-ohm. This value is changed according to the input capacitance of the apparatus connected after the difference amplifier 210 and the amplified signal frequency. Furthermore, the amplifying rate of the difference amplifier 210 is not limited to a positive value of at least 1 and is an arbitrary value. The difference amplifier 210 may have a function for amplifying the difference between the two input signals and is not limited to the structure described previously. Unless specifically written, the other difference amplifiers denoted in this specification have the structure shown in FIG. 6. The difference amplifier denoted in this specification may output the difference signal of at least two input signals and may have a structure other than the structure in FIG. 6.

The T&H 220 is a 2-channel track-and-hold circuit, simultaneously holds two mutually independent input signals, and independently outputs the respective hold result. For example, the T&H 220 has the structure shown in FIG. 7. Specifically, the T&H 220 comprises a switch SW₁ for turning on and off the input signal Tᵢₙ₁ a capacitor C₁ for holding the output level of switch SW₁, a switch SW₂ for turning on and off the input signal Tᵢₙ₂, and a capacitor C₂ for holding the output level of switch SW₂. The switches SW₁ and SW₂ operate in response to the input sampling pulses CLK. Since the capacitors C₁ and C₂ are fabricated in LSI, the capacitances thereof are assumed to be at most 1 picofarad. In the drawing, Vss is a negative voltage source.

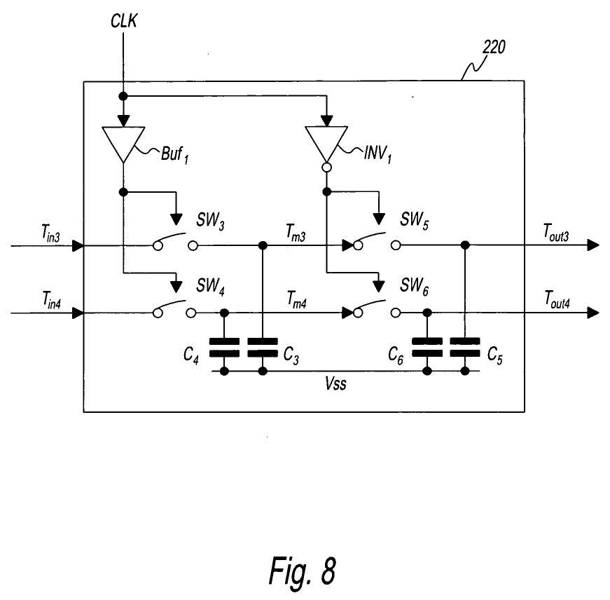

When the T&H 220 has the structure shown in FIG. 7, the signals input during the tracking period are transmitted nearly unchanged to later connected circuits and apparatus. If signal leakage is to be avoided for the later connected circuits and apparatus, the master-slave track-and-hold circuit shown in FIG. 8 is an acceptable structure for the T&H 220. In FIG. 8, the T&H 220 comprises a switch SW₃ for turning on and off the input signal Tᵢₙ₃, a capacitor C₃ for holding the output level of switch SW₃, a switch SW₄ for turning on and off the input signal Tᵢₙ₄ a capacitor C₄ for holding the output level of switch SW₄, a switch SW₅ for turning on and off the middle signal Tₘ₃ that represents the hold level of capacitor C₃, a capacitor C₅ for holding the output level of switch SW₅, a switch SW₆ for turning on and off the middle signal Tₘ₄ that represents the hold level of capacitor C₄, a capacitor C₆ for holding the output level of switch SW₆, a buffer Buf₁, and an inverter INV₁. Switches SW₃, SW₄, SW₅, and SW₆ operate in response to the sampling pulses CLK. The sampling pulses CLK are supplied through the buffer Buf₁ to switches SW₃ and SW₄ and through the inverter INV₁ to switches SW₅ and SW₆. Since the capacitors C₃, C₄, C₅, and C₆ are fabricated in LSI, the capacitances thereof are assumed to be at most 1 picofarad. In the drawing, Vss is a negative source voltage.

Next, the operation of the analog to digital converting apparatus 200 is explained. FIG. 5 is referenced. The difference amplifier 210 amplifies the difference signal between the signal under test Vᵢₙ, and the reference signal Vref output by the DAC 140 and outputs to the T&H 220. The T&H 220 holds the difference output signal of the difference amplifier 210 in response to the logic level of the sampling pulses CLK. The comparator 250 compares the levels of the positive signal and the negative signal of the held difference signal and outputs the comparison result Cₒᵤₜ₂. The comparison result Cₒᵤₜ₂ of the comparator 250 is output as logic level “H” or “L”. If the held positive signal level is greater than the held negative signal level, the logic level “H” is output. If the held negative signal level is greater than the held positive signal level, logic level “L” is output. The SAR 130 judges the output signal Cₒᵤₜ₂ of the comparator 250 and new data are output in response to the rising edges of the sampling pulses CLK. At this time, the SAR 130 updates the content of the internal register. The DAC 140 outputs a new reference signal V_{ref} based on the new data output by the SAR 130.

There is no regular signal stability period in the output signal of the difference amplifier 210. To solve this problem, the T&H 220 holds the output signal of the difference amplifier 210 in response to the sampling pulses CLK. Therefore, the output signal of the difference amplifier 210 is held at the prescribed time positions of the signal under test Vᵢₙ. Since the signal under test Vᵢₙ is a repeating signal, the output signal of the difference amplifier 210 is only held at the same time positions of the signal under test Vᵢₙ, and the same value is held each time. The analog to digital converting apparatus 200 uses this effect to perform the successive approximation.

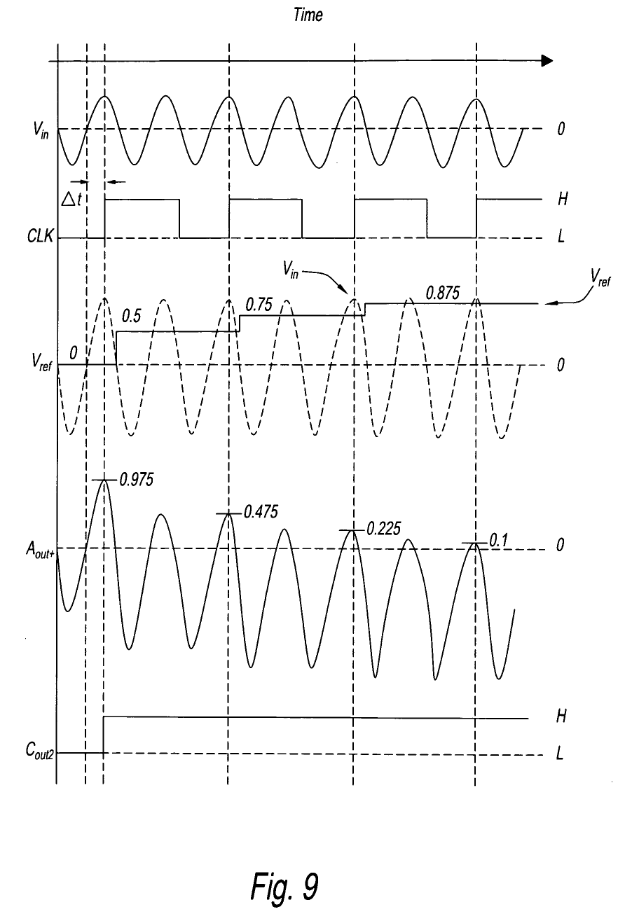

Next, FIGS. 5 and 9 are referenced. FIG. 9 shows the changes over time of the signal under test Vᵢₙ, sampling pulses CLK, reference signal V_{ref}, positive output signal Aₒᵤₜ₁₊ of the difference amplifier 210, and output signal Cₒᵤₜ₂ in FIG. 5. In FIG. 9, the horizontal axis is the time, and the vertical axis is the amplitude or the logic level. At the time on the left end of the graph, the output data of the SAR 130 is “1000”, and the output signal level of the DAC 140 is zero. The bit sequence representing the data content indicates the most significant bit on the left end and the least significant bit on the right end. The sampling pulses CLK are generated at the time positions offset by only Δt from the zero crossings of the rise times of the signal under test Vᵢₙ. The instantaneous value of the signal under test Vᵢₙ at the time position offset by only Δt is 0.975.

In FIG. 9, at the time of the rising edge of the initial, that is, the first from the left sampling pulse CLK, the instantaneous value of the signal under test Vᵢₙ is 0.975, the reference signal Vref is zero, and the positive output signal Aₒᵤₜ₁₊ of the difference amplifier 210 is 0.975. Consequently, the logic level of the output signal output signal Cₒᵤₜ₂ is “H”. As a result, the output data of the SAR 130 becomes “1100”, and the reference signal V_{ref} output from the DAC 140 becomes 0.5.

At the time of the rising edge of the next, that is, the second from the left sampling pulse CLK, the instantaneous value of the signal under test Vᵢₙ is similarly 0.975, the reference signal V_{ref} is 0.5, and the positive output signal Aₒᵤₜ₁₊ of the difference amplifier 210 is 0.475. Consequently, the logic level of the output signal Cₒᵤₜ₂ is “H”. As a result, the output data of the SAR 130 becomes “1110”, and the reference signal V_{ref} output from the DAC 140 becomes 0.75.

At the time of the rising edge of the next, that is, the third from the left sampling pulse CLK, the instantaneous value of the signal under test Vᵢₙ, is similarly 0.975, the reference signal V_{ref} is 0.75, and the positive output signal Aₒᵤₜ₁₊ of the difference amplifier 210 is 0.225. Consequently, the logic level of the output signal Cₒᵤₜ₂ is “H”. As a result, the output data of the SAR 130 becomes “1111”, and the reference signal V_{ref} output from the DAC 140 becomes 0.875.

At the time of the rising edge of the next, that is, the fourth from the left sampling pulse CLK, the instantaneous value of the signal under test Vᵢₙ is 0.975, the reference signal V_{ref} is 0.875, and the positive output signal Aₒᵤₜ₁₊ of the difference amplifier 210 is 0.1. Consequently, the logic level of the output signal Cₒᵤₜ₂ is “H”. Then the analog to digital conversion ends. When the next analog to digital conversion starts, the SAR 130 initializes the internal register and sets the output data to “1000”.

As explained above, in the analog to digital converting apparatus 200, the signal inputs to the comparator 250 are held by the T&H 220. Therefore, compared to the comparator 110 in the analog to digital converting apparatus 100 of the first embodiment, the operating speed demanded in the comparator 250 is lowered. In addition, since the comparator 250 may operate at a relatively slow speed, the sensitivity to the input signal is easily improved. Furthermore, in the analog to digital converting apparatus 200, if the output signal of the difference amplifier 210 is held at the prescribed time position of the signal under test Vᵢₙ, the level accuracy demanded in the means 220 for holding the output signal of the difference amplifier 210 is lowered to 1 bit and can perform successive-approximation analog to digital conversion similar to conventional conversion.

According to the first embodiment and the second embodiment, if the relative time positions with respect to the signal under test Vᵢₙ are the same, even if the time positions have different absolute time positions, the values held at the time positions are all identical. This can also be applied when the accuracy demanded in the entire analog to digital conversion is shared by a plurality of T&Hs. This embodiment is explained as a third embodiment.

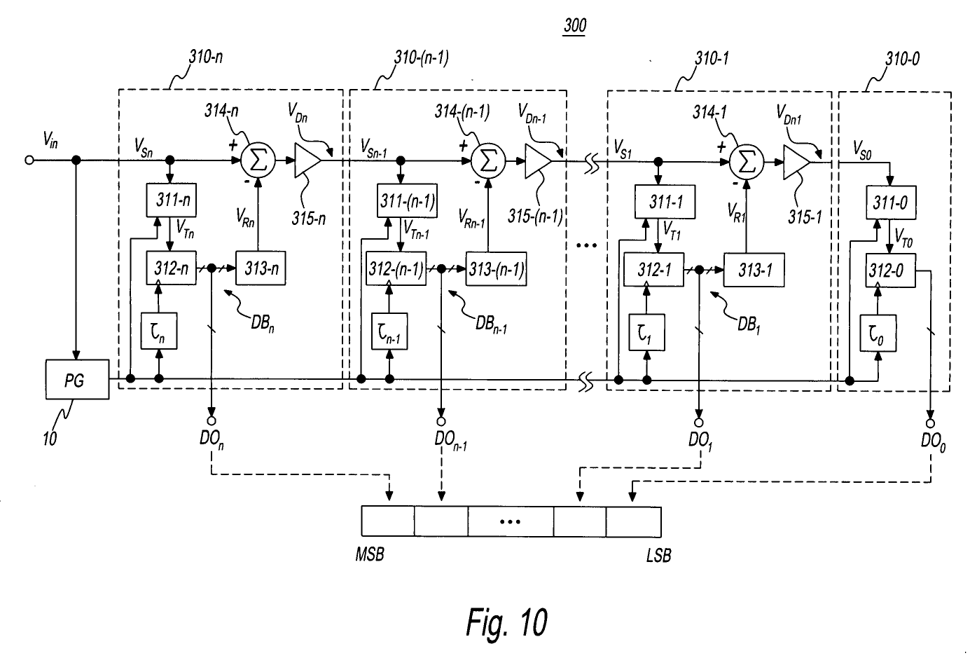

A third embodiment of the present invention is an analog to digital converting apparatus providing a plurality of analog to digital converting parts connected by pipeline and incorporated into an integrated circuit. FIG. 10 is a block diagram of an analog to digital converting apparatus 300, which is a third embodiment of the present invention. In FIG. 10, the analog to digital converting apparatus 300 has the following structure.

The analog to digital converting apparatus 300 comprises n analog to digital converting parts 310-n, where n is a positive integer of 1 or more, having signal input and signal output; an analog to digital converting part 310-0 having signal input; and a pulse generator 10. The analog to digital converting part 310-n and the analog to digital converting part 310-0 are connected in a pipeline. The signal under test Vᵢₙ is inputted to the analog to digital converting apparatus 300. The pulse generator 10 is the same as the apparatus shown in FIG. 1. The output signal CLK of the pulse generator 10 is supplied to analog to digital converting part 310-n and analog to digital converting part 310-0. The sampling pulses CLK that are the output signal of pulse generator 10 are the pulses generated at the time positions offset by only some arbitrary time Δt from the zero crossings of the rise times of the signal under test Vᵢₙ.

The analog to digital converting part 310-n comprises a track-and-hold circuit 311-n, an analog to digital converter 312-n, a digital to analog converter 313-n, a subtracter 314-n, and an amplifier 315-n. The sampling pulses CLK are supplied to T&H 311-n and to ADC 312-n through the delay τₙ. T&H 311-n is an apparatus for holding the input signal V_{Sn} in response to the sampling pulses CLK. ADC 312-n is an apparatus for performing the analog to digital conversion of the output signal V_{Tn} of T&H 311-n in response to the rising edges of the sampling pulses CLK. DAC 313-n is an apparatus for performing the digital to analog conversion of the digital data, which is the analog to digital conversion result. The subtracter 314-n is an apparatus for subtracting the reference signal V_{Rn}, which is the conversion result of DAC 313-n, from the input signal V_{Sn}. The amplifier 315-n is an apparatus for amplifying the output signal of the subtracter 314-n. The output signal V_{Dn} of the amplifier 315-n is the output signal of the analog to digital converting part 310-n. The delay τₙ is a delay of at least the propagation delay time of the T&H 311-n in order to eliminate the effect of the propagation delay of the T&H 311-n, and is added to the input signal. The ADC 312-n, DAC 313-n, and data output terminal DOₙ are connected by the data bus DBₙ. The width of the data bus DBₙ is at least 1 bit. The resolution of the ADC 312-n and the resolution of the DAC 313-n are equal and at least 1 bit. As explained above, n is a positive integer of at least 1. Consequently, the analog to digital converting part 310-1, for example, comprises T&H 311-1, ADC 312-1, DAC 313-1, subtracter 314-1, amplifier 315-1, delay τ₁, data bus DB₁, and data output terminal DO₁. The output signal V_{Dn} of the analog to digital converting part 310-n is input to the analog to digital converting part 310-(n−1) in a later stage. For example, the output signal V_{D5} of the analog to digital converting part 310-5 is input to the analog to digital converting part 310-4 in a later stage.

The analog to digital converting part 310-0 comprises a track-and-hold circuit 311-0, an analog to digital converter 312-0, and a data output terminal DO₀. The sampling pulses CLK are supplied to T&H 311-0 and to ADC 312-0 through the delay τ₀. The T&H 311-0 holds the input signal V_{S0} in response to the sampling pulses CLK. ADC 312-0 is an apparatus for performing the analog to digital conversion of the output signal V_{T0} of T&H 311-0 in response to the rising edges of the sampling pulses CLK. The delay τ₀ is the delay of at least the propagation delay time of T&H 311-0 in order to eliminate the effect of the propagation delay of T&H 311-0 and is added to the input signal. ADC 312-0 and data output terminal DO₀ are connected by data bus DB₀. The width of the data bus DB₀ is at least 1 bit. ADC 312-0 is at least 1 bit.

The digital data output from the data output terminal DOₙ and the digital data output from the data output terminal DO₀ are linked in the connection order to form one digital data. The concatenated digital data is the result of the analog to digital conversion of the signal under test Vᵢₙ, by the analog to digital converting apparatus 300.

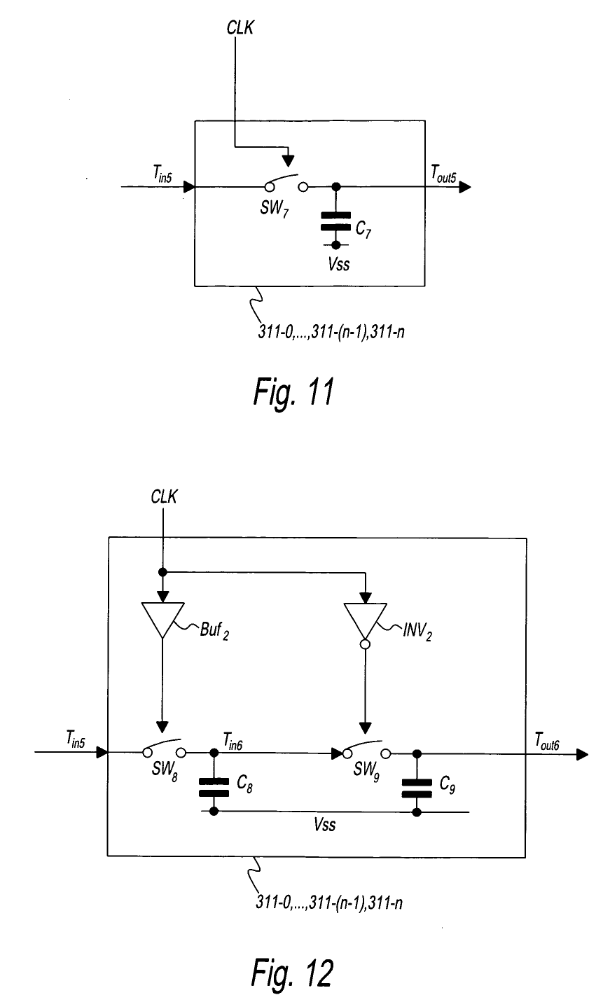

T&H 311-n to T&H 311-1 and T&H 311-0 are single-channel track-and-hold circuits. For example, T&H 311-n to T&H 311-1 and T&H 311-0 have the structure shown in FIG. 11. Each of T&H 311-n to T&H 311-1 and T&H 311-0 comprises a switch SW₇ for turning on and off the input signal Tᵢₙ₅ and a capacitor C₇ for holding the output level of the switch SW₇. Switch SW₇ operates in response to the input sampling pulses CLK. Since capacitor C₇ is fabricated in LSI, the capacitance thereof is assumed to be at most 1 picofarad.

When T&H 311-n and T&H 311-0 have the structure shown in FIG. 11, the input signal is transmitted nearly unchanged to later circuits and apparatus during the tracking period. If signal leakage is to be avoided for the later connected circuits and apparatus, the master-slave track-and-hold circuit shown in FIG. 12 is an acceptable structure for T&H 311-n to T&H 311-1 and T&H 311-0. In FIG. 12, each of T&H 311-n to T&H 311-1 and T&H 311-0 comprises a switch SW₈ for turning on and off the input signal Tᵢₙ₆, a capacitor C₈ for holding the output level of switch SW₈, a switch SW₉ for turning on and off the middle signal Tₘ₆ that represents the hold level of the capacitor C₈, a capacitor C₉ for holding the output level of switch SW₉, a buffer Buf₂, and an inverter INV₂. Switches SW₈ and SW₉ operate in response to the sampling pulses CLK. The sampling pulses CLK are supplied through buffer Buf₂ to switch SW₈ and through inverter INV₂ to SW₉. Since capacitors C₈ and C₉ are fabricated in LSI, the capacitances thereof are assumed to be at most 1 picofarad.

When a difference signal is input to T&H 311-n to T&H 311-1 and T&H 311-0, T&H 311-n to T&H 311-1 and T&H 311-0 may adopt the structures shown in FIG. 7 or 8.

Next, while referring to FIG. 10, the operation of the analog to digital converting apparatus 300 is explained.

In the analog to digital converting part 310-n in the first stage, T&H 311-n holds the input signal V_{Sn} in response to the sampling pulses CLK. Next, ADC 312-n performs the analog to digital conversion of the output signal V_{Tn} of T&H 311-n. After the analog to digital conversion by ADC 312-n, the digital data is output as the conversion result to DAC 313-n and data output terminal DOₙ from ADC 312-n. DAC 313-n outputs the signal V_{Rn} based on the given digital data.

In the analog to digital converting part 310-(n−1) in the next stage, T&H 311-(n−1) holds the input signal V_{Sn-1} in response to the sampling pulses CLK. Next, ADC 312-(n−1) performs the analog to digital conversion of the output signal V_{Tn-1} of T&H 311-(n−1). After the analog to digital conversion by ADC 312-(n−1), the digital data is output as the conversion result to DAC 313-(n−1) and data output terminal DOₙ₋₁ from ADC 312-(n−1). DAC 313-(n−1) outputs the signal V_{Rn-1} based on the given digital data. The output signal V_{Tn-1} to be converted is the input signal V_{Sn-1} held after the completion of the analog to digital conversion by ADCₙ. If the conversion process of ADC 312-(n−1) needs a time interval of at least one period of the sampling pulses CLK, the output signal V_{Tn-1} of T&H 311-(n−1) must be constant during the conversion processing period of ADC 312-(n−1). Therefore, the output signal V_{Rn} of at least DACₙ is held at a constant level during the period requiring a constant output signal V_{Tn-1} of T&H 311-(n−1) to be held during the conversion processing period of ADC 312-(n−1).

In later stages, the same process is implemented up to the analog to digital converting part 310-1.

In the analog to digital converting part 310-0, which is the final stage, T&H 311-0 holds the input signal V_{S0} in response to the sampling pulses CLK. Next, ADC 312-0 performs the analog to digital conversion of the output signal V_{T0} of T&H 311-0. After the analog to digital conversion by ADC 312-0, the digital data is output as the conversion result from ADC 312-0 to data output terminal DO₀. The output signal V_{T0} to be converted is the input signal V_{S0} held after the completion of the analog to digital conversion by ADC 312-1. If the conversion processing by ADC 312-0 requires a time interval of at least one period of the sampling pulses CLK, the output signal V_{T0} of T&H 311-0 must be constant during the conversion processing period of ADC 312-0. Therefore, the output signal V_{R1} of at least DAC 313-1 is held at a constant level during the period requiring a constant output signal V_{T0} of T&H 311-0 to be held during the conversion processing period of ADC 312-0.

After the conversion processing by ADC 312-0 ends, the digital data obtained from each of the data output terminals DOₙ to DO₁ and DO₀ are combined, and the conversion result of the analog to digital converting apparatus 300 is generated. The digital data obtained from data output terminal DOₙ is assigned to the most significant position. The digital data obtained from data output terminal DO₀ is assigned to the least significant position. At the intermediate position, the digital data obtained from each of data output terminals DOₙ₋₁ to DO₁ are assigned in order. The digital data obtained from each of data output terminals DOₙ to DO₁ and DO₀ are related to the same Δt. In other words, these digital data are the respective analog to digital conversions of the output signals V_{Tn} to V_{T1} and V_{T0} at the time positions offset by only an arbitrary time Δt from the zero crossings at the rise times of the signal under test Vᵢₙ.

As is clear from the above description, since all of T&H 311-n to T&H 311-1 and T&H 311-0 are disposed between the backbone of the pipeline and the input terminal of each ADC, and the difference signal VDₙ is held by T&H 311-(n−1) in the least significant position in the first stage at the prescribed time position Δt of the signal under test Vᵢₙ the level accuracy demanded by the analog to digital converting apparatus 300 can be shared by a plurality of T&Hs and a plurality of ADCs. For example, the level accuracy demanded by T&Hₙ may have better resolution than ADCₙ. The same applies to T&H 311-n to T&H 311-1 and T&H 311-0. As a precaution, the backbone of the pipeline is a signal line passing through each analog to digital converting part. In other words, the backbone of the pipeline is an analog signal line that does not pass through ADC and DAC.

Next, one example of the case where n=1, that is, a 2-stage pipelined analog to digital converting apparatus is explained below as a fourth embodiment. An analog to digital converting apparatus 400, which is the fourth embodiment of the present invention, comprises an analog to digital converting part 400-1 in the front stage and an analog to digital converting part 400-0 in the last stage. The analog to digital converting apparatus 400 has the configuration where the analog to digital converting part 400-1 is a successive-approximation ADC.

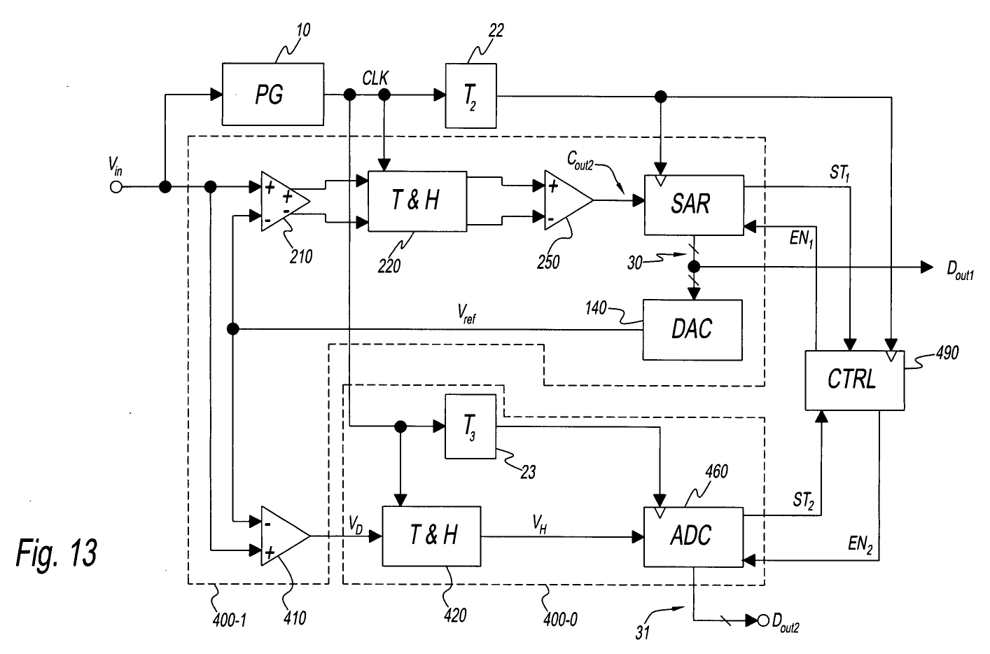

FIG. 13 is now referenced. FIG. 13 is a block diagram of the analog to digital converting apparatus 400 incorporated into an integrated circuit, which is the fourth embodiment of the present invention. The analog to digital converting apparatus 400 includes an analog to digital converting apparatus 200. Consequently, in FIG. 13, the identical structural elements in FIG. 5 are assigned the same reference numbers and the detailed descriptions thereof are omitted. In FIG. 13, the analog to digital converting apparatus 400 is structured as follows.

The analog to digital converting apparatus 400 comprises a pulse generator 10, a delay 22, a difference amplifier 210, a track-and-hold circuit 220 (T&H 220), a comparator 250, a successive-approximation register 430 (SAR 430), a digital to analog converter 140 (DAC 140), a delay 23, a difference amplifier 410, a track-and-hold circuit 420 (T&H 420), an analog to digital converter 460 (ADC 460), and a controller 490. The analog to digital converting apparatus 400 inputs the signal under test Vin. The sampling pulses CLK output by the pulse generator 10 are supplied to T&H 220 and T&H 420, to SAR 430 through delay 22, and to ADC 460 through delay 23. The sampling pulses CLK are the pulses generated at the time positions offset by only Δt from the zero crossings at the rise times of the signal under test Vᵢₙ. The delay 22 adds a delay of at least the propagation delay time of the T&H 220 to the input signal in order to eliminate the effect of the propagation delay of the T&H 220. The delay 23 adds a delay of at least the propagation delay time of the T&H 420 to the input signal in order to eliminate the effect of the propagation delay of the T&H 420. T&H 220 and T&H 420 hold the input signal in response to the sampling pulses CLK. In addition, the SAR 430 and the ADC 460 operate in response to the rising edges of the sampling pulses CLK. T&H 420 holds the output signal VD of the difference amplifier 410. The reference signal Vref that is the output signal of DAC 140 and the signal under test Vᵢₙ are input to the difference amplifier 410. The signal V_{H} held by the T&H 420 is input to the ADC 460. ADC 460 outputs the conversion data through the data bus 31 to the data output terminal Dₒᵤₜ₂. SAR 430 adds a function for transmitting the status signal ST₁ for determining the operating state of the SAR 430 and a function for receiving the control signal EN₁ that externally controls the operation of the SAR 430 to the SAR 130. ADC 460 has a function for transmitting status signal ST₂ for notifying the operating state of ADC 460 and a function for receiving the control signal EN₂ for externally controlling the operation of ADC 460. The controller 490 is an apparatus for controlling the operations of the SAR 430 and the ADC 460 by receiving status signal ST₁ and status signal ST₂, and transmitting control signal EN₁ and control signal EN₂. In this embodiment, the register length (resolution) of the SAR 430, the resolution of the DAC 140, and the width of the data bus 30 are each 4 bits. In practice, these values may be other than 4 bits. The resolution of the ADC 460 and the width of the data bus 31 are each 6 bits. In practice, these values may be other than 6 bits.

Next, the operation of the analog to digital converting apparatus 400 is explained.

First, the controller 490 outputs the control signal EN₂, and analog to digital conversion of the most significant 4 bits are implemented by the SAR 430. At this time, the ADC 460 enters the wait state by the control signal EN₁ output by the controller 490. The SAR 430 performs the actual analog to digital conversion of the signal under test Vᵢₙ, at the time positions offset by only an arbitrary time Δt from the zero crossings at the rise times of the signal under test Vᵢₙ and outputs the digital data as the conversion result to the DAC 140 and the data output terminal Dₒᵤₜ₁. The DAC 140 outputs the signal V_{ref} based on the given digital data. The output signal V_{ref} corresponds to V_{R1} in FIG. 10. The analog to digital conversion by the SAR 430 is explained in the description of the second embodiment. When the analog to digital conversion ends, the SAR 430 outputs the status signal ST₁, and the end of the conversion is notified to the controller 490. Then, the controller 490 outputs control signal EN₁, and the SAR 430 enters the wait state. Next, the controller 490 outputs control signal EN₂, and the analog to digital conversion of the least significant 6 bits is implemented by the ADC 460.

The ADC 460 performs the analog to digital conversion of the output signal V_{H} of the T&H 420. The output signal V_{H} to be converted is the output signal V_{D} of the difference amplifier 410 held after the output signal V_{ref} of the DAC 140 was stabilized after the analog to digital converter by the SAR 430. After the analog to digital conversion by the ADC 460, digital data are output as the conversion result from the ADC 460 to the data output terminal Dₒᵤₜ₂. When the conversion process by the ADC 460 requires a time period of at least one period of the sampling pulses CLK, the output signal V_{H} of T&H 420 must be constant during the conversion processing period of the ADC 460. Consequently, the output signal V_{ref} of at least DAC 140 is held at a constant level during the period where the output signal V_{H} of the T&H 420 must be held at a constant value during the conversion processing period of the ADC 460. When the analog to digital conversion ends, the ADC 460 outputs the status signal ST₂, and the end of the conversion is notified to the controller 490. Then, the controller 490 sets the ADC 460 in the wait state for the specified time. After the specified time elapses, the controller 490 outputs the control signal EN₁ and performs the analog to digital conversion of the most significant 4 bits again in the ADC 460. The above-mentioned operation is repeated by the controller 490.

During the wait states of the SAR 430 and the ADC 460, 10-bit data are obtained where the conversion result of the SAR 430 obtained from data output terminal Dₒᵤₜ₁ is set to the most significant 4 bits and the conversion result of the ADC 460 obtained from data output terminal Dₒᵤₜ₂ is set to the least significant 6 bits. This 10-bit data becomes the conversion result of the analog to digital converting apparatus 400. The conversion result of the SAR 430 and the conversion result of the ADC 460 are linked to the same Δt. Namely, the conversion result of the SAR 430 and the conversion result of the ADC 460 are based on the output signals of T&H 220 and T&H 420 held at time positions offset by only an arbitrary time Δt from the zero crossings at the rise times of the signal under test Vᵢₙ.

Similar to analog to digital converting apparatus 300, the level accuracy demanded by the analog to digital converting apparatus 400 can be shared by T&H 220 for the most significant positions and T&H 420 for the least significant positions.

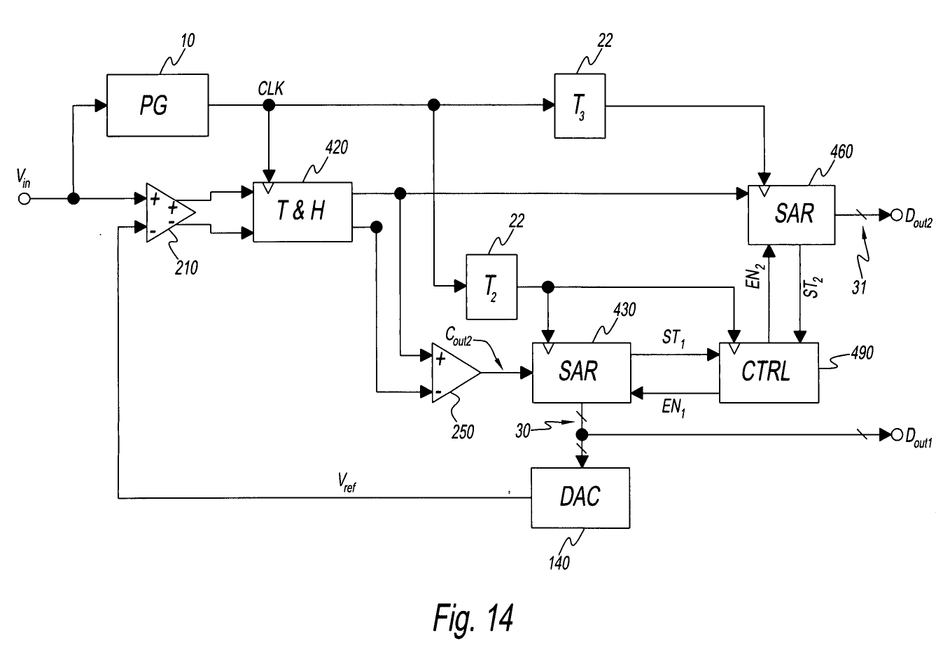

Difference amplifier 210 and difference amplifier 410 can be shared. Similarly, T&H 220 and T&H 420 can be shared. When this sharing is employed, the analog to digital converting apparatus 400 shown in FIG. 13 is changed as in FIG. 14. In FIG. 14, the same structural elements as in FIG. 13 are assigned the same reference numbers. An analog to digital converting apparatus 500 shown in FIG. 14 is a fifth embodiment of the present invention. The operation of analog to digital converting apparatus 500 is nearly identical to that of analog to digital converting apparatus 400. In the description of the operation of the analog to digital converting apparatus 400, T&H 220 can be reread as T&H 420 and difference amplifier 410 as difference amplifier 210. Analog to digital converting apparatus 500 has the advantage of circuit scale compared to analog to digital converting apparatus 400.

As is clear from the above description, the level accuracy demanded by the T&H 420 can surpass the resolution of the ADC 460. In the analog to digital converting apparatus 500, the difference signal between the signal under test Vᵢₙ and the signal V_{ref} generated based on the conversion result of the SAR 430 that is equivalent to the most significant analog to digital conversion is held by the T&H 420 at the prescribed time position Δt of the signal under test Vᵢₙ. Therefore, although the track-and-hold circuit provided in the analog to digital converting apparatus 500 is only the T&H 420, the level accuracy demanded in the T&H 420 does not have to exceed the level accuracy demanded in the analog to digital converting apparatus 500, but may have the resolution of the analog to digital conversion means (ADC 460 in this case) having the highest resolution from a plurality of analog to digital conversion means connected after the track-and-hold circuit 420.

The analog to digital converting apparatus of the first, second, third, fourth, and fifth embodiments described above were explained with the entire apparatus incorporated into an integrated circuit. In BIST, in addition to the ability to incorporate the test apparatus into an integrated circuit, there is a demand for a smaller region occupied by the test related circuits formed in the integrated circuit. Therefore, an embodiment having the smallest possible occupied region in the integrated circuit is described below.

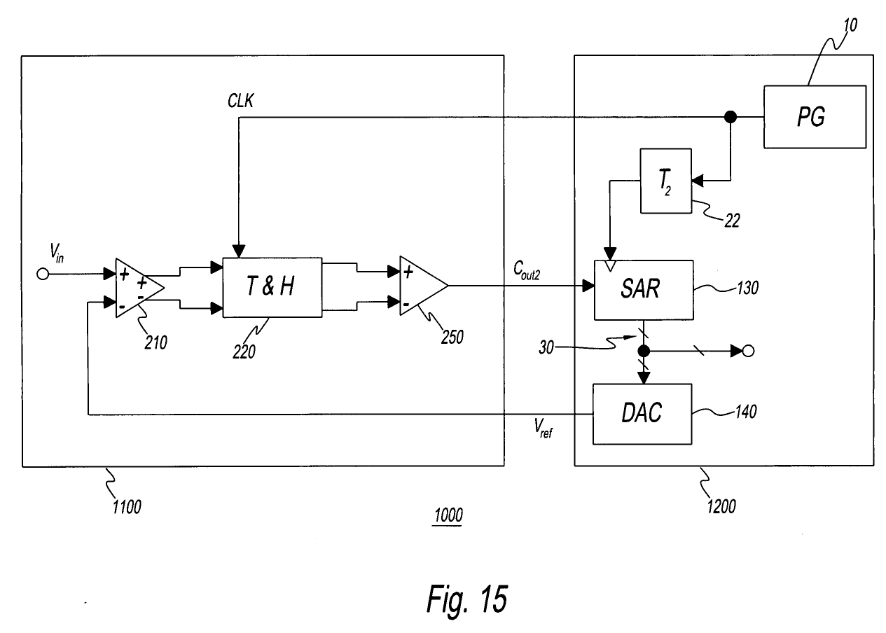

A sixth embodiment of the present invention is implemented as an apparatus that incorporates a portion of the analog to digital converting apparatus 200 of the second embodiment in the integrated circuit and the remainder is externally connected to the integrated circuit. The sixth embodiment is a test system 1000 constructed from an integrated circuit 1100 incorporating a track-and-hold component and a test apparatus 1200 implementing an analog to digital converter. FIG. 15 is a block diagram of the test system 1000. In FIG. 15, the integrated circuit 1100 comprises a difference amplifier 210, a track-and-hold circuit 220 (T&H 220), and a comparator 250. T&H 220 is a master-slave track-and-hold circuit. The test apparatus 1200 is an apparatus for observing the signal under test Vᵢₙ in the integrated circuit 1100 and comprises a pulse generator 10, a delay 22, a SAR 130, and a DAC 140. The operation of the test system 1000 is identical to the analog to digital converting apparatus 200. As is clearly seen in FIG. 15, the signals Cₒᵤₜ₂ and V_{ref} related to the signal under test Vᵢₙ that are exchanged between the integrated circuit 1100 and the test apparatus 1200 are regarded as DC within at least one period of a sampling pulse CLK. The DC signals are easily handled with high precision compared to high frequency signals. Consequently, the test apparatus 1200 does not require expensive components for highly accurate analog to digital conversion of the signal under test Vᵢₙ. The difference amplifier 210, the track-and-hold circuit 220 with at most 1-bit precision, and the relatively slow comparator 250 are easily fabricated by a CMOS process. The comparator 250 can be provided in the test apparatus 1200 and not by the integrated circuit 1100.

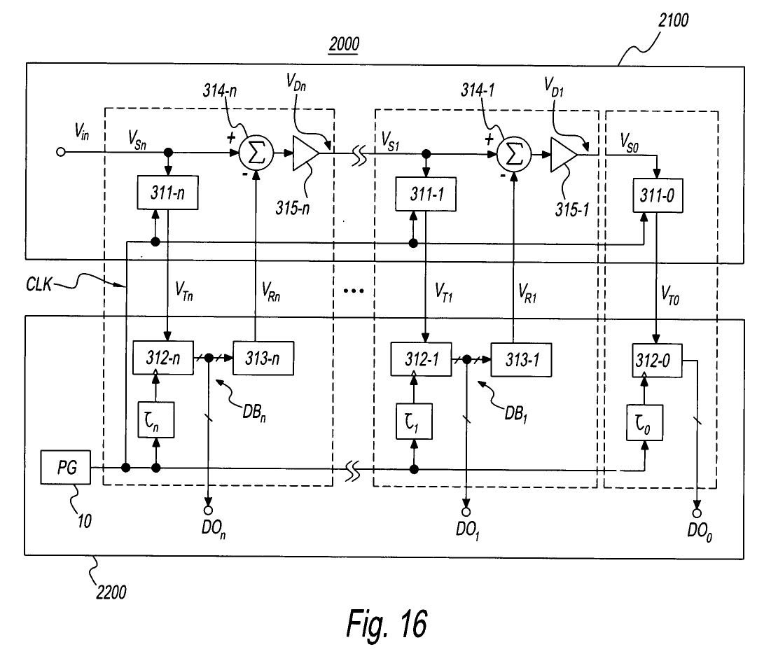

A seventh embodiment of the present invention implements an apparatus for incorporating a portion of the analog to digital converting apparatus 300 of the third embodiment in the integrated circuit and the remainder is externally connected to the integrated circuit. The seventh embodiment is a test system 2000 constructed from an integrated circuit 2100 incorporating a track-and-hold component and a test apparatus 2200 implementing an analog to digital converter. FIG. 16 is a block diagram of the test system 2000. In FIG. 16, the integrated circuit 2100 comprises T&H 311-n to T&H 311-1 and T&H 311-0, subtracter 314-n to subtracter 314-1 and subtracter 314-0, and amplifier 315-n to amplifier 315-1 and amplifier 315-0. T&H 311-n to T&H 311-1 and T&H 311-0 are master-slave track-and-hold circuits. The test apparatus 2200 is an apparatus for observing the signal under test Vᵢₙ in the integrated circuit 2100 and comprises a pulse generator 10, ADC 312-n to ADC 312-1 and ADC 312-0, DAC 313-n to DAC 313-1 and DAC 313-0, and delay τₙ to delay τ₁ and delay τ₀. The operation of the test system 2000 is identical to that of the analog to digital converting apparatus 300. As is clearly seen from FIG. 16, the signals V_{Tn} to V_{T1} and V_{T0}, which are related to the signal under test Vᵢₙ, and signals V_{Rn} to V_{R1} and V_{R0} that are exchanged between the integrated circuit 2100 and the test apparatus 2200 are regarded as DC in at least one period of a sampling pulse CLK. Consequently, the test apparatus 2200 no longer requires expensive parts for high-precision analog to digital conversion of the signal under test Vᵢₙ. T&H 311-n to T&H 311-1 and T&H 311-0 can lower the demanded precision and are easily fabricated by CMOS processes. Furthermore, subtracter 314-n to subtracter 314-1 and subtracter 314-0 can use difference amplifiers and are easily fabricated by CMOS processes.

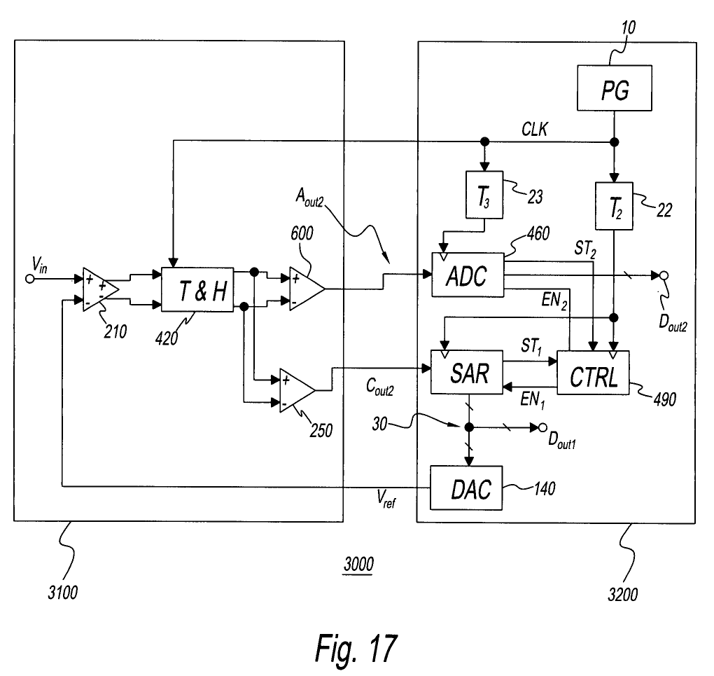

An eighth embodiment of the present invention is an apparatus where a portion of the analog to digital converting apparatus 500 of the fifth embodiment is incorporated in the integrated circuit and the remainder is externally connected to the integrated circuit. The eighth embodiment is a test system 3000 constructed from an integrated circuit 3100 incorporating the track-and-hold component and a test apparatus 3200 implementing an analog to digital converter. FIG. 17 is a block diagram of the test system 3000. In FIG. 17, the integrated circuit 3100 comprises a difference amplifier 210, a track-and-hold circuit 420 (T&H 420), a comparator 250, and a single end positive output difference amplifier 600. T&H 420 is a master-slave track-and-hold circuit. The test apparatus 3200 is an apparatus for observing the signal under test Vᵢₙ in the integrated circuit 3100 and comprises a pulse generator 10, a delay 22, a delay 23, a SAR 430, a DAC 140, an ADC 460, and a controller 490. The operation of the test system 3000 is identical to that of analog to digital converting apparatus 500. The output signal of the difference amplifier 600 is Aₒᵤₜ₂. As is seen from FIG. 17, signals Aₒᵤₜ₂, Cₒᵤₜ₂ and V_{ref} related to the signal under test Vᵢₙ that are exchanged between the integrated circuit 3100 and the test apparatus 3200 are regarded as DC in one period of at least one sampling pulse CLK. Consequently, the test apparatus 3200 no longer needs to provide expensive parts for the high-precision analog to digital conversion of the signal under test Vᵢₙ. Difference amplifier 210, difference amplifier 600, relatively slow comparator 250, and relatively low precision track-and-hold circuit 420 are easily fabricated by CMOS processes.

In the sixth, seventh, and eighth embodiments, the pulse generator 10 has the structure shown in FIG. 2. However, the input signal Vᵢₙ to the ramp generator in FIG. 2 is not only the signal under test Vᵢₙ, but may be other signals synchronized to the signal under test Vᵢₙ. For example, a clock signal generated in the test apparatus in each embodiment is also acceptable. Usually, the integrated circuit to be tested is supplied the clock signal generated in the test apparatus and operates. In this case, the clock signal generated in the test apparatus is synchronized to the signal under test Vᵢₙ. The pulse generator 10 may be provided in the integrated circuit.

In the embodiments of the present invention described above, if the pulse generation positions each offset slightly by Δt sweep at least one period of the signal to be tested, the entire waveform of the signal under test can be observed.

In the embodiments of the present invention described above, all or a part of an analog to digital converting apparatus may be incorporated in an integrated circuit that differs from the test subject. In the embodiments of the present invention described above, the T&H is an example having an extremely simple structure using resistors and capacitors, but a T&H having a form including operational amplifiers is also acceptable.

Furthermore, in the embodiments of the present invention described above, the FF holding the comparison result of the comparator can be replaced by a latch.

In the embodiments of the present invention described above, the T&H can be replaced by a sample-and-holding circuit (S&H) or another signal holding means.

Furthermore, in the embodiments of the present invention described above, the comparator and the FF 120 holding the comparison result of the comparator can be replaced by a latch comparator.

Furthermore, in the embodiments of the invention described above, when a difference amplifier having a differential output is changed to a single end output, the later connected T&H is changed to the one-channel structure as shown in FIG. 11 or 12, and the negative input terminal of the later connected comparator may be connected to ground.

1. A signal holding method is a method for holding a repeating signal for analog to digital conversion, wherein the signal holding method comprises:
comparing the repeating signal to a reference signal, and
holding the comparison result at the prescribed time positions of the repeating signal.

2. The signal holding method according to claim 1 further comprising:
generating the reference signal by the analog to digital conversion of the repeating signal at the prescribed time positions before the time of holding the comparison result and digital to analog conversion of the analog to digital conversion result.

3. The signal holding method according to claim 1, wherein the comparison result is a logic signal showing the magnitude relationship between the repeating signal and the reference signal.

4. The signal holding method according to claim 1, wherein the comparison result is a difference signal between the repeating signal and the reference signal.

5. The signal holding method according to claim 1, wherein the prescribed time positions are positions offset by a specified time interval from the times where the repeating signal satisfies prescribed conditions.

6. A signal holding apparatus is an apparatus for holding a repeating signal for analog to digital conversion and comprises
a comparator for comparing the repeating signal and a reference signal, and
a signal holder for holding the comparison result at the prescribed time position of the repeating signal.

7. The signal holding apparatus according to claim 6, further comprising a generator for generating the repeating signal by performing the analog to digital conversion of the repeating signal at the prescribed time position before the time holding the comparison result and performing the digital to analog conversion of the analog to digital conversion result.

8. The signal holding apparatus according to claim 6, wherein the comparison result is a logic signal indicating the magnitude relationship between the repeating signal and the reference signal.

9. The signal holding apparatus according to claim 6, wherein the comparison result is the difference signal between the repeating signal and the reference signal.

10. The signal holding apparatus according to claim 6, wherein the prescribed time positions are positions offset by a specified time interval from the times where the repeating signal satisfies prescribed conditions.

11. An analog to digital converting method is a method for performing the analog to digital conversion of the repeating signal, said method comprising:
performing the analog conversion of the digital data and generating the reference signal,
comparing the repeating signal and the reference signal,
holding the comparison result at the prescribed time position of the repeating signal,
adjusting the digital data based on the held comparison result, and
outputting the digital data as the result of the analog to digital conversion.

12. The analog to digital converting method according to claim 11, wherein at least the signal generation step, the signal comparison step, the comparison result holding step, and the digital data adjusting step are repeated until the held comparison result satisfies prescribed conditions.

13. The analog to digital converting method according to claim 11, wherein the comparison result is a logic signal indicating the magnitude relationship between the repeating signal and the reference signal.

14. The analog to digital converting method according to claim 11, wherein the comparison result is a difference signal between the repeating signal and the reference signal.

15. The analog to digital converting method according to claim 12, wherein the comparison result is a difference signal between the repeating signal and the reference signal, and the analog to digital converting method further comprises:
after the held comparison result satisfies prescribed conditions, fixing the digital data, performing the analog to digital conversion of the held comparison result, and outputting the conversion result as the least significant data of the digital data.

16. The analog to digital converting method according to claim 11, wherein the prescribed time positions are positions offset by a specified time interval from the times when the repeating signal satisfies prescribed conditions.

17. An analog to digital converting apparatus is an apparatus for performing the analog to digital conversion of the repeating signal, said apparatus comprises:
a converter for performing the analog conversion of digital data and generating the reference signal,
a comparator for comparing the repeating signal and the reference signal,
a signal holder for holding the comparison result at the prescribed time position of the repeating signal,
means for adjusting the digital data based on the held comparison result, and
means for outputting the digital data as the result of the analog to digital conversion.

18. The analog to digital converting apparatus according to claim 17, wherein at least the signal generation in the signal generator, the comparison in the signal comparator, the holding in the comparison result signal holder, and the adjustment in the digital data adjusting means are repeated until the held comparison result satisfies prescribed conditions.

19. The analog to digital converting apparatus according to claim 17, wherein the comparison result is a logic signal indicating the magnitude relationship between the repeating signal and the reference signal.

20. The analog to digital converting apparatus according to claim 17, wherein the comparison result is a difference signal between the repeating signal and the reference signal.

21. The analog to digital converting apparatus according to claim 18, wherein the comparison result is a difference signal between the repeating signal and the reference signal, and the analog to digital converting apparatus provides:
means for analog to digital conversion which after the held comparison result satisfies prescribed conditions, fixes the digital data, performs the analog to digital conversion of the held comparison result, and outputs the conversion result as the least significant data of the digital data.

22. The analog to digital converting apparatus according to claim 17, wherein the prescribed time positions are positions offset by a specified time interval from the time when the repeating signal satisfies prescribed conditions.

23. An analog to digital converting method for performing analog to digital conversion of a repeating signal in a device under test, said method comprising:
applying pulses generated at the prescribed time positions of the repeating signal to the device under test,
performing the analog conversion of digital data and applying the generated reference signal to the device under test,
receiving the held comparison result from the device under test in response to the pulses where the comparison result in the device under test is between the repeating signal and the reference signal, and adjusting the digital data based on the received result, and
outputting the digital data as the result of analog to digital conversion.

24. The analog to digital converting method according to claim 23, wherein at least the pulse application step, reference signal application step, and digital data adjusting step are repeated until the received result satisfies prescribed conditions.

25. The analog to digital converting method according to claim 23, wherein the comparison result is a logic signal indicating the magnitude relationship between the repeating signal and the reference signal.

26. The analog to digital converting method according to claim 23, wherein the comparison result is a difference signal between the repeating signal and the reference signal.

27. The analog to digital converting method according to claim 24, further comprising: after the held comparison result satisfies prescribed conditions, fixing the digital data, performing an analog to digital conversion of the held comparison result, and outputting the conversion result as the least significant data from the digital data where the comparison result is a difference signal between the repeating signal and the reference signal.

28. The analog to digital converting method according to claim 23, wherein the prescribed time positions are positions offset by a specified time interval from the times when the repeating signal satisfies the specified conditions.

29. An analog to digital converting apparatus for performing the analog to digital conversion of a repeating signal in a device under test, said apparatus comprising:
a generator for applying pulses generated at the prescribed time positions of the repeating signal to the device under test,
means for applying the reference signal generated by the analog conversion of digital data to the device under test,
means for adjusting the digital data based on the received result where there is a comparison result in the device under test between the repeating signal and the reference signal and the comparison result held in response to a pulse is received from the device under test, and
means for outputting the digital data as the result of analog to digital conversion.

30. The analog to digital converting apparatus according to claim 29, wherein at least the signal application in the pulse generator, the signal application in the reference signal application means, and the adjustment in the digital data adjusting means are repeated until the received result satisfies prescribed conditions.

31. The analog to digital converting apparatus according to claim 29, wherein the comparison result is the difference signal between the repeating signal and the reference signal.

32. The analog to digital converting apparatus according to claim 29, wherein the comparison result is the logic signal indicating the magnitude relationship between the repeating signal and the reference signal.

33. The analog to digital converting apparatus according to claim 30, wherein the comparison result is a difference signal between the repeating signal and the reference signal, and the analog to digital converting apparatus comprises:
means for analog to digital conversion which after the held comparison result satisfies prescribed conditions, fixes the digital data, performs the analog to digital conversion of the held comparison result, and outputs the comparison result from the digital data as the least significant data.

34. The analog to digital converting apparatus according to claim 29, wherein the prescribed time positions are positions offset by a specified time interval from the times when the repeating signal satisfies prescribed conditions.

35. A pipelined analog to digital converting apparatus that provides a plurality of analog to digital converting parts and performs the analog to digital conversion of the repeating signal, wherein:
said analog to digital converting parts provide analog to digital conversion, digital to analog conversion, signal holding, and calculations,
signals input to the analog to digital converting parts are each applied to a signal holder and a calculator,
said signal holder holds the signals input to the analog to digital converting parts at the prescribed time position of the repeating signal,
said analog to digital converting parts performs the analog to digital conversion of the output signal of said signal holder,
said analog to digital converting part performs the analog conversion of the digitalized output signal of said signal holder (or the result of the analog to digital conversion), and
said calculator determines the difference between the signal input to the analog to digital converting parts and the result of the digital to analog conversion.

36. The pipelined analog to digital converting apparatus according to claim 35, wherein the prescribed time positions are positions offset by a specified time interval from the times when the repeating signal satisfies prescribed conditions.
